(19) United States
(12) Patent Application Publication
(10) Pub. No.: US 2012/0212920 A1
(43) Pub. Date: Aug. 23, 2012

(54) CIRCUIT CARD ASSEMBLIES HAVING CONNECTOR-LESS PERPENDICULAR CARD-TO-CARD INTERCONNECTS

(75) Inventor: Gary Schreffler, Winter Park, FL (US)

(73) Assignee: LOCKHEED MARTIN CORPORATION, Bethesda, MD (US)

(21) Appl. No.: 13/031,479

(22) Filed: Feb. 21, 2011

(51) Int. Cl. H05K 1/14; H05K 3/36

(52) U.S. Cl. 361/803; 29/830

(57) ABSTRACT

A coupled circuit card assemblies (CCCA) includes a first CCA (CCA1) having at least one board receiving side aperture including electrical conductor lined through-holes above and/or below the aperture. A second CCA (CCA2) has surface electrical conductors proximate to one of its edges (“connectable edge”). The connectable edge of CCA2 penetrates into the board receiving side aperture of CCA1 to provide a perpendicular attachment including a plurality of reinforced joints including a low temperature flowable material that electrically connects respective surface conductors on at least one of the top side and bottom sides of CCA2 to respective electrical conductor lined through-holes on CCA1. The low temperature flowable material can be solder.

### FIELD

Disclosed embodiments relate to circuit card assemblies having compact card-to-card electrical interconnects.

### BACKGROUND

As known in the data processing art and as used herein, a circuit card assembly (CCA) generally includes multiple processor, memory and other electrical components that are generally soldered to a printed circuit board (PCB) also known as a printed wiring board (PWB). CCAs are commonly used for computing or data processing systems. The boards comprise a dielectric material known as the substrate, and include at least one thin layer of electrically conducting material such as copper for interconnecting the respective electrical components on the board and providing coupling to input/output (I/O) connections. The electrically conducting material is deposited or “printed” on the surface of the board. The board substrate most commonly used in PCBs is a glass fiber reinforced (fiberglass) epoxy resin with a copper foil bonded on to one or both sides that provides metal traces for interconnection. In the case of multi-layer board substrates, embedded metal layers are included.

The interconnection of two or more CCAs provides what is referred to herein as a coupled circuit card assemblies (CCCA). CCCAs are advantageous in the design of large scale processing and computing systems, which includes avionics systems which are designed for aircraft. One of the design criteria for an avionics system is that the system take up as little room as possible. In most avionic designs, each CCA is placed in a box and is positioned in a parallel fashion relative to the other CCAs. This design has the advantage that the layout of the boards takes up as little room as possible and the shortest electrical path between and within the CCA is obtained.

In order to make electrical connections between CCAs, connectors coupled to the I/Os on the CCA are mounted on each CCA for interconnection to I/Os of other CCAs. The interconnects generally comprise wire (solid or multi-strand conductors), surface mount, through hole or compliant pin connectors, or terminals which generally take up large amounts of valuable board surface area. For example, when multiple CCAs are installed on an aircraft, there are very stringent requirements for flight applications which limit the selection of connectors available for use on both commercial and military aircraft. In a harsh environment such as experienced by an airplane, the connectors must provide robust electrical connections that can tolerate environmental factors such as vibration and large changes in temperature.

### SUMMARY

Disclosed embodiments include a coupled circuit card assembly (CCCA) comprising connector-less perpendicular card-to-card interconnects. The CCCA comprises a first CCA (CCA1) having at least one board receiving side aperture including electrical conductor lined through-holes above and/or below the board receiving side aperture. A second CCA (CCA2) has surface electrical conductors that provide contact pads proximate to one of its edges (“connectable edge”). The connectable edge of CCA2 penetrates into the board receiving side aperture CCA1 to provide a perpendicular attachment including a plurality of reinforced joints comprising a low temperature flowable material that provides an electrically connection for coupling signals between the CCAs. As used herein, a “low temperature flowable conducting material” is an electrically conductive material that flows at a temperature ≦300° C. sufficient to form a low resistance electrical joint between respective CCAs, such as solder or a soft metal that can be press fit, such as copper or a copper alloy.

The reinforced joints provide at least partially filled volumes above and/or below CCA2 in fillable interface regions defined by at least one non-solder electrically conducting feature in the electrical conductor lined through-holes. The reinforced joints can include the non-solder electrically conducting feature embedded in solder 1 that electrically connects surface conductors the top and/or bottom side of CCA2 to electrical conductor lined through-holes on CCA1. Disclosed reinforced joints can reliably tolerate high-g force conditions, such as >3 g experienced by fighter pilots and in the case of reinforced solder joints, can comprise gap-free reinforced solder joints that can tolerate at least 10,000 g's.

### BRIEF DESCRIPTION OF THE DRAWINGS

FIGS. 1A and B comprise a side depiction of a first CCA (CCA1) and a second CCA (CCA2), respectively, before penetration of CCA2 into a board receiving side aperture of CCA1 to form a CCCA, where the CCAs are both single-sided CCAs, according to an example embodiment.

FIGS. 2A and B comprise a side depiction of CCA1 and CCA2, respectively, before penetration of CCA2 into a board receiving side aperture of CCA1, where the CCAs are both double-sided CCAs, according to an example embodiment.

FIG. 3A is a depiction of an example CCCA showing an edge of CCA1 and an edge of CCA2, where the CCAs are both double-sided CCAs, with CCA2 including wires interconnects coupled to surface electrical conductors on both its top side and bottom sides located proximate to one of its edges penetrated into the board receiving aperture of CCA1, according to an example embodiment.

FIG. 3B is a depiction of the example CCCA shown in FIG. 3A showing an edge of CCA2 penetrated into a board receiving aperture of CCA1 showing solder embedded wires in the electrical conductor lined through-holes above and below the board receiving aperture, according to an example embodiment.

FIG. 4 is a depiction of an example CCCA wherein CCA1 includes a plurality of board receiving side apertures, each penetrated by other CCAs, according to an example embodiment.

FIG. 5 is a flow chart showing steps in an example method of assembling a CCCA having connector-less perpendicular card-to-card interconnects, according to an example embodiment.

### DETAILED DESCRIPTION

Disclosed embodiments are described with reference to the attached figures, wherein like reference numerals, are used throughout the figures to designate similar or equivalent elements. The figures are not drawn to scale and they are provided merely to illustrate aspects disclosed herein. Several disclosed aspects are described below with reference to example applications for illustration. It should be understood that numerous specific details, relationships, and methods are set forth to provide a full understanding of the embodiments disclosed herein. One having ordinary skill in the relevant art, however, will readily recognize that the disclosed embodiments can be practiced without one or more of the specific details or with other methods. In other instances, well-known structures or operations are not shown in detail to avoid obscuring aspects disclosed herein. Disclosed embodiments are not limited by the illustrated ordering of acts or events, as some acts may occur in different orders and/or concurrently with other acts or events. Furthermore, not all illustrated acts or events are required to implement a methodology in accordance with this Disclosure.

Disclosed embodiments include CCCAs that have connector-less perpendicular card-to-card interconnects that can be applied to single-sided CCAs or dual-sided CCAs. The board substrates can comprise a wide array of substrates including single layer or multi-layer substrates, film-based substrates (e.g. polyimide), organic laminates, ceramic, or other composite materials.

Disclosed CCCAs include a CCA referred to herein as CCA1 that includes at least one board receiving side aperture having a plurality of electrical conductor lined through-holes (e.g., vias) that provide I/O connections for CCA1 located above and/or below the board receiving side aperture. At least another CCA, referred to herein as CCA2, has surface electrical conductors that provide I/Os for CCA2 on at least one of its top side and bottom side that are located proximate to one of its edges (“connectable edge”). As used herein, “proximate” to an edge includes distances up to 300 thousandths of an inch (=0.762 cm). The connectable edge of CCA2 penetrates into the board receiving side aperture of CCA1 to provide a perpendicular attachment including a plurality of reinforced low temperature flowable material comprising joints suitable for communicating signals between the CCAs.

The reinforced joints comprise at least partially filled volumes above and/or below CCA2 in fillable interface regions defined by spaces between the non-solder electrically conducting features in the electrical conductor lined through-holes. As noted above, the low temperature flowable conducting material can comprise solder or a low temperature press fittable material, such as a copper or a copper alloy.) For example, the two CCAs can be press fit together using a soft electrically conductive material between the two CCAs soft enough to cold (e.g., 25° C.) flow by pres fitting to provide a low resistance electrical signal path.

The reinforced joints comprise at least one non-solder electrically conducting feature (e.g., metal wire or lead) at least partially surrounded by solder or a polymer such as an epoxy in the press fit embodiment. The reinforced joints electrically connect respective surface conductors on the top side and/or bottom side of CCA2 to respective ones of the plurality of electrical conductor lined through-holes on CCA1. The non-solder electrically conducting features (e.g., metal wire, stamped conductor, or a lead) partially fill the through-holes space in the interface region to add strength to the joint by assisting holding of the respective CCAs together, such as to tolerate vibration and high-g force conditions (e.g., >3 g experienced by fighter pilots).

The non-solder electrically conducting features such as wires, stamped conductors or leads in the interface regions result in larger fillets which can provide added strength for the joints. Thus high g-force tolerant CCCAs having connector-less perpendicularly-joined CCAs that couple signals between the respective CCAs are provided by disclosed embodiments. The added strength provided by disclosed embodiments is needed for high g applications, which is generally defined as 3 g or above.

For embodiments where the low temperature flowable conductive material comprises solder, such embodiments recognize non-solder electrically conducting features such as wires, stamped conductors or leads improve solder wetting by capillary action that acts to suck solder in to the joint to help avoid solder starved joints. For solder embodiments the reinforced solder joints can comprise gap-free reinforced solder joints, where “gap-free” is defined herein as providing ≧98% volume filling, typically ≧99% volume filling. Gap-free solder joints minimize solder voids that can lead to cracking on the CCA due to differences in the coefficient of thermal expansion (CTE) between the board substrate and the joint materials.

For example, missiles and other military projectiles can be subject to g-forces of 10,000 to 60,000 g's during flight. Super high g-force application are defined herein as those subject to ≧10,000 g's. For such super-high g-force applications, solder used as the low temperature flowable conductive material to form reinforced solder joints has been unexpectedly found to be able to tolerate g-forces of at least 10,000 g. For super-high g-force applications the boards can be secured by clamping or bonding to a structural element. If the CCAs contain components with significant mass so that the board cannot survive such as due to the tearing of its conductors, a potting compound can be used to reinforce the CCCA. Thus, by including disclosed reinforced solder joints, and appropriate board reinforcements, disclosed CCCAs can be used for super-high g-force applications.

Disclosed connector-less card-to-card connecting structures also eliminate the need for conventional connectors that can take up valuable board area. As noted above, conventional CCA-to-CCA connectors such as wire (solid or multi-strand conductors), surface mount, through-hole or compliant pin connectors can take up large amounts of CCA surface area.

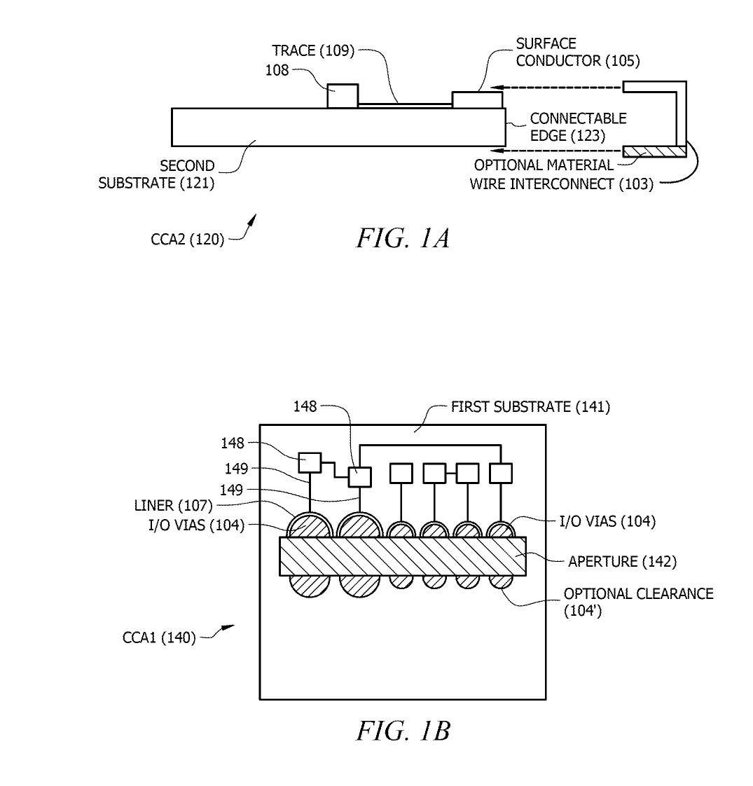

FIGS. 1A and B comprise a side depiction of a second CCA (CCA2) 120 comprising a second substrate 121 and a first CCA (CCA1) 140 comprising a first substrate 141, respectively, before penetration of CCA2 120 into a board receiving side aperture 142 of CCA1 140 formed in the first substrate 141 to form a CCCA, where the CCAs are both single-sided CCAs, according to an example embodiment.

CCA2 120 is shown including one of its surface electrical conductors 105 that each function as a contact pad on the surface of the second substrate 121 to accommodate the non-solder electrically conducting features shown in FIG. 1A as a wire interconnect 103 there over. The non-solder electrically conducting feature such as the wire interconnect 103 shown in FIG. 1A can be sized (e.g., diameter) based on maximum current density requirements of the electronic circuitry on CCA2, such as electronic circuitry 108 that is shown coupled by metal trace 109 to surface conductor 105 on CCA2 120. Wire interconnect 103 is shown including an optional portion that is labeled as “optional material” in FIG. 1A. CCA1 140 is also shown including electronic circuitry 148 that is shown coupled to the I/O vias 104 by traces 149. After the wire interconnect 103 is coupled to the surface conductor 105 on CCA2 the wire interconnect covered edge of CCA2 120 becomes a connectable edge 123 that can be inserted into board receiving aperture 142 of CCA1 140.

The conductor lined through-holes 104 shown as I/O vias 104 on CCA1 140 include an electrically conductive lining 107, such as comprising a copper, gold or gold alloys such as Electroless Nickel/Immersion Gold (ENIG), that can sized based on size of the non-solder electrically conducting features (e.g., wire interconnect 103) to be received. CCA1 140 is shown including optional clearance 104′ that provides vias for clearance on the bottom of aperture 142 to allow mating in embodiments where the wire interconnect 103 or other non-solder electrically conducting feature includes the optional material shown in FIG. 1A. The sizes of the conductor lined through-holes 104 on CCA1 140 in FIG. 1B are shown including larger size I/O vias 104 for receiving relatively large diameter wire 103 and relatively smaller size conductor I/O vias 104 that can receive smaller diameter wire. As described below, multiple wire interconnects 103 may be assembled together in a single step over surface conductors 105 of CCA2 120 using a dissolvable carrier based on particular I/O needs.

The non-solder electrically conducting features 103 such as wire or leads are formed from a material that can be selected to not melt during solder reflow operation (e.g., generally 300 to 400° C.) should solder be chosen as the low temperature flowable material. For example, metals or metal alloys including copper, copper plated by silver, or other relatively high melting point materials that solder will adhere to (wet), such as nickel, palladium and platinum may be used. As known in the art of soldering, wetting means the molten solder leaves a continuous permanent film on the metal surface, and solder is a fusible metal alloy with a melting point or melting range generally in a range from 160 to 280° C.

The wire interconnects 103 or other non-solder electrically conducting features are generally placed on CCA2 120 before insertion of CCA2 into CCA1. Wire interconnects 103 may be bent by a suitable bending to provide proper spacing (based on the thickness of second substrate 121 plus the thickness of surface conductor 105) and shape shown in FIG. 1A before placement on CCA2 120.

CCA1 140 is generally designed such that the I/O electrical conductor lined through-holes shown as I/O vias 104 are in a line and the via diameter (or other shape, such as a slot, or ellipse) is large enough to accept the wire interconnect 103 with a small added dimension for filling in the case of solder filling. CCA1 140 has a board receiving side aperture 142 shown as a slot that is just large enough for CCA2 120 to be inserted into CCA1 140 with the wire interconnects 103 in place. One way CCA2 120 can slide into CCA1 140 is by providing enough clearance in the board receiving side aperture 142 of CCA1 140 for the wire interconnect 103 to provide clearance on both sides (top and bottom) of the aperture 142. Another option is to cut the wire interconnects 103 such that the wire interconnects 103 do not wrap around the edge of CCA2 120 before insertion. As described below, after insertion of CCA2 120 into CCA1 140, in one embodiment wire interconnects 103 or other non-solder electrically conducting features can then be soldered in the interface region to form a reinforced solder joint between CCA1 and CCA2, where CCA1 140 is attached perpendicular with respect to CCA2 120.

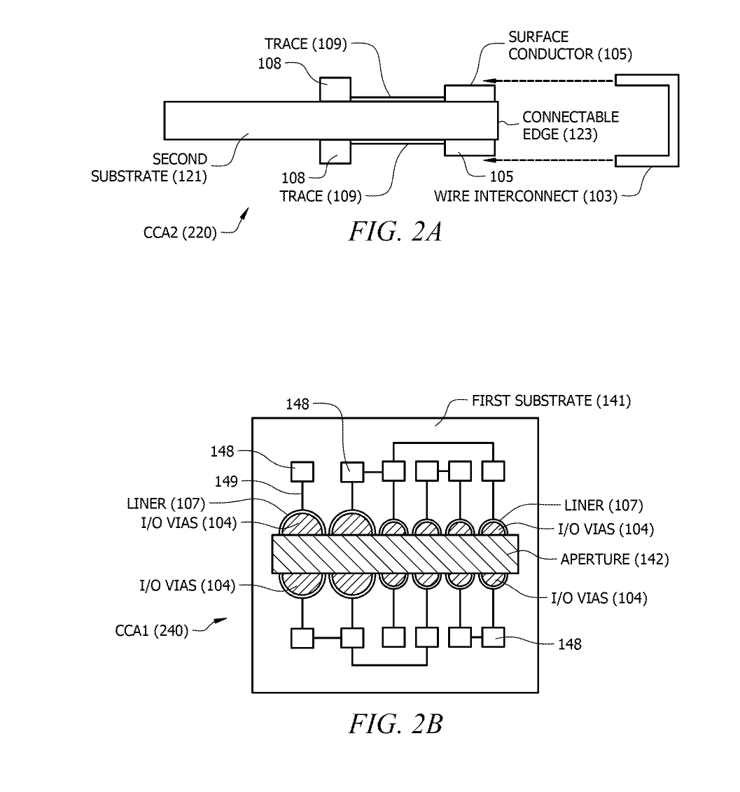

FIGS. 2A and B comprise a side depiction of CCA1 240 and CCA2 220, respectively, before penetration of CCA2 220 into a board receiving side aperture 142 of CCA1 240, where the CCAs are both double-sided CCAs, according to an example embodiment. As described below, after insertion of the connectable edge 123 of CCA2 220 into aperture 142 of CCA1 240, the wire interconnects 103 or other non-solder electrically conducting features can be cut to provide two separate electrically isolated conductors to double the number of I/O connection provided for the CCCA.

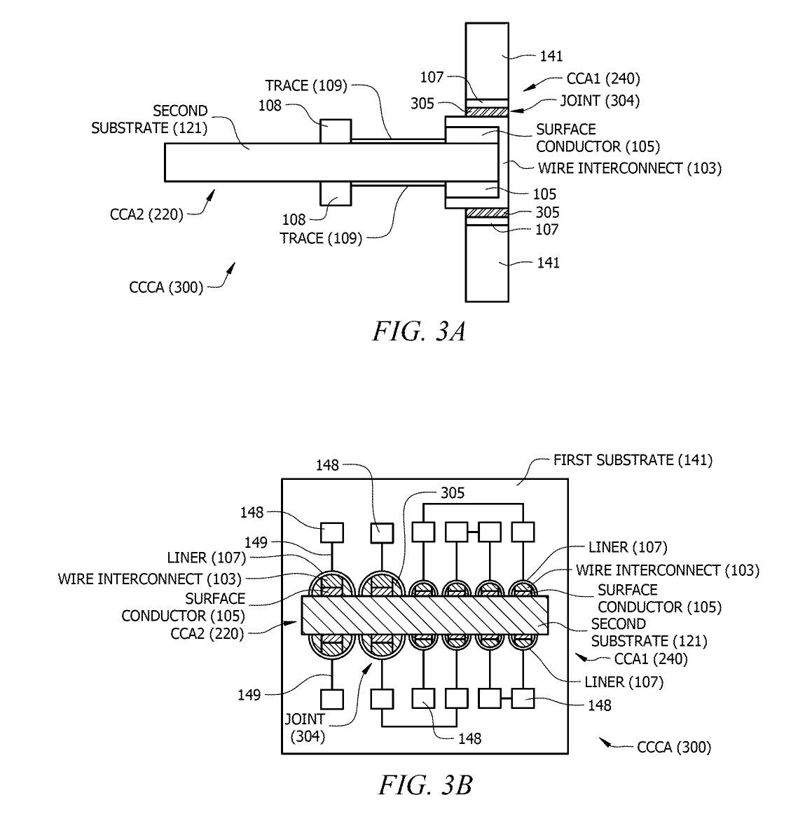

FIG. 3A is a depiction of an example CCCA 300 showing an edge of CCA1 240 shown in FIG. 2B and an edge of CCA2 220, where the CCAs are both double-sided CCAs, with CCA2 including wires coupled to surface electrical conductors on both its top side and bottom sides located proximate to one of its edges penetrated into CCA1, according to an example embodiment. FIG. 3B is a depiction of the of an example CCCA shown in FIG. 3A showing an edge of CCA2 220 penetrated into a board receiving side of CCA1 240 showing solder embedded wires in the electrical conductor lined through-holes above and below the board receiving aperture provided by CCA1 240, according to an example embodiment.

Reinforced joints 304 are shown both above and below CCA2 220 can comprise a low temperature flowable material 305 such as solder and a non-solder electrically conducting feature shown as wire 103 embedded in the solder 305 that electrically connects respective ones of said surface conductors 105 on both the top side and bottom sides of CCA2 220 to respective ones of the electrical conductor lined 107 through-holes 104 provided by CCA1 240. Although FIG. 3A shows CCA2 220 not fully penetrating CCA1 240, in another embodiment CCA2 220 fully penetrates CCA1 240.

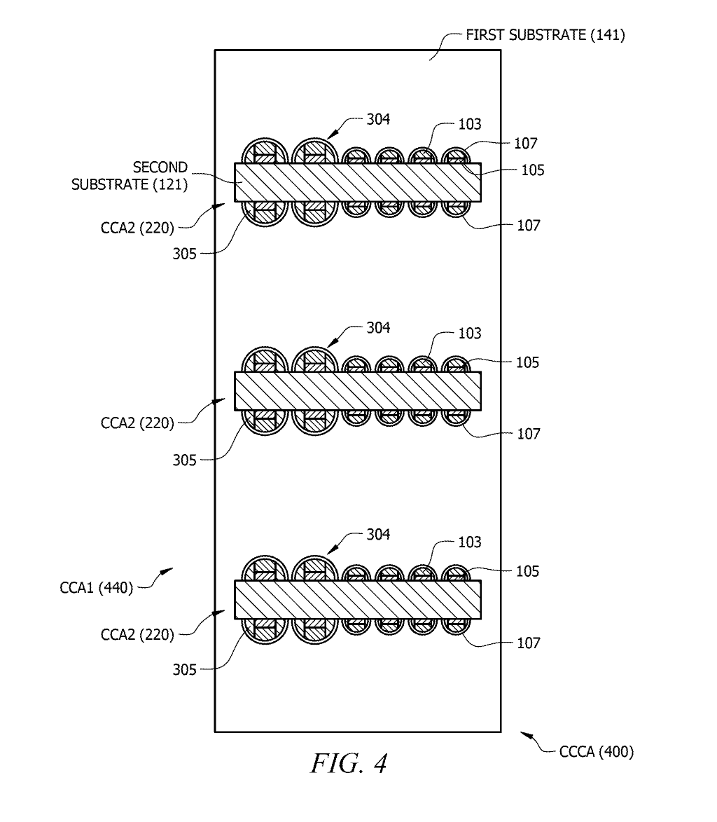

FIG. 4 is a simplified depiction of an example CCCA 400 wherein CCA1 440 is CCA1 240 shown in FIG. 2B modified to include a plurality of board receiving side apertures 142, with each board receiving aperture 142 penetrated by a CCA2 220, according to an example embodiment. This embodiment allows a large number of disclosed reinforced I/O connections.

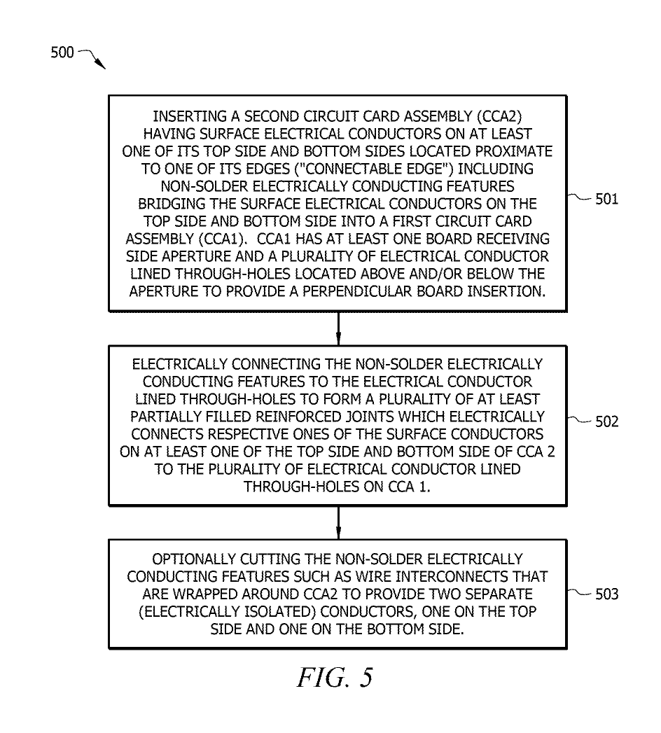

FIG. 5 is a flow chart showing steps in an example method 500 of assembling a CCCA having connector-less perpendicular card-to-card interconnects, according to an example embodiment. Step 501 comprises inserting a second circuit card assembly (CCA2) having surface electrical conductors on its top side and/or bottom sides located proximate to one of its edges (“connectable edge”) including non-solder electrically conducting features bridging the surface electrical conductors on the top side and bottom side into a first circuit card assembly (CCA1) having at least one board receiving side aperture and a plurality of electrical conductor lined through-holes located above and/or below the board receiving side aperture to provide a perpendicular board insertion of the connectable edge of CCA2. The distance between CCA1 240 liner 107 and the CCA2 220 surface conductor 105 can be controlled to within 0.001 inches. Upon board insertion, the non-solder electrically conducting features such as wires wrap around CCA2, and friction can hold the attachment in place prior to completing the joints.

Step 502 comprises electrically connecting the non-solder electrically conducting features to the electrical conductor lined through-holes to form a plurality of at least partially filled reinforced joints which electrically connects the non-solder electrically conducting feature to respective ones of the surface conductors on the top side and/or bottom side of CCA2 to the plurality of electrical conductor lined through-holes on CCA1. In the case of solder, the solder fills the joint space, provides part of the electrical pathway, and embeds the non-solder electrically conducting feature (e.g., metal wire or lead).

In the case of a press fit joint, the non-solder electrically conducting features are press fit to the electrical conductor lined through-holes which can then be followed by adding a dielectric filling material such as an epoxy monomer after press fitting. In the case of epoxy, the epoxy can then be cured. The epoxy does not have to fill the entire gap, since the non-solder electrically conducting feature 103 largely fills the gap during press fitting.

Step 503 comprises optionally cutting the non-solder electrically conducting features such as wire interconnects that are wrapped around CCA2 to provide two separate (electrically isolated) conductors, one on the top side and one on the bottom side. Since there can be a dielectric (e.g., tape, plastic, or acrylic) holding the non-solder electrically conducting features such as wires in place before inserting (step 501), such as added before a wire bending step, the non-solder electrically conducting features can be drilled, including automated laser drilling, such that the wires or other non-solder electrically conducting features wrapped around CCA1 can become two separate conductors, one on the top side and one on the bottom side. The quantity (number) of I/O interconnects can thus be doubled for every cut.

Advantages of disclosed embodiments include elimination of connector bodies that take up valuable surface area of the CCA. Moreover, multiple current carrying conductors positioned anywhere within the interface can be conveniently reworked, if needed, since each individual non-solder electrically conducting feature such as a wire can be removed, opening the circuit if a circuit change is needed. As noted above, such interfaces can be formed using automatic laser soldering for assembly. Moreover, for two board embodiments, two relatively simple PCBs that can be used with disclosed embodiments that cost significantly less as compared to a rigid flex. In addition, preformed and adjoined buss wires can be used for the non-solder electrically conducting features that cost significantly less as compared to conventional connectors.

As described above, disclosed embodiments provide reduced cost as compared to known card-to-card assembly methods and can reduce the board surface area needed for the interconnections. Disclosed methods also lend themselves to automation, including forming (i.e. bending) the non-solder electrically conducting feature to fit around CCA2 and/or installing the non-solder electrically conducting features such as wires on CCA2. Automation is also possible for the insertion/attachment to mate the CCAs together, as well as filling the fillable interfaces such as using laser soldering or hot air soldering the interfaces. Press fitting for forming press fitted joints may also be automated. Accordingly, disclosed embodiments can be used in a variety of commercial and military applications. For example, disclosed embodiments can be used for advanced sensors data transmission and communications systems integration, and for applications subject to g forces of 3 g or more, including applications such as missiles subject to 10,000 s of g's.

While various disclosed embodiments have been described above, it should be understood that they have been presented by way of example only, and not as a limitation. Numerous changes to the disclosed embodiments can be made in accordance with the Disclosure herein without departing from the spirit or scope of this Disclosure. Thus, the breadth and scope of this Disclosure should not be limited by any of the above-described embodiments. Rather, the scope of this Disclosure should be defined in accordance with the following claims and their equivalents.

Although disclosed embodiments have been illustrated and described with respect to one or more implementations, equivalent alterations and modifications will occur to others skilled in the art upon the reading and understanding of this specification and the annexed drawings. While a particular feature may have been disclosed with respect to only one of several implementations, such a feature may be combined with one or more other features of the other implementations as may be desired and advantageous for any given or particular application.

The terminology used herein is for the purpose of describing particular embodiments only and is not intended to be limiting to this Disclosure. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof are used in either the detailed description and/or the claims, such terms are intended to be inclusive in a manner similar to the term “comprising.”

I claim:

1. A coupled circuit card assemblies (CCCA), comprising:
a first circuit card assembly (CCA1) comprising a first substrate having at least one board receiving side aperture in said first substrate having a plurality of electrical conductor lined through-holes located above and below said board receiving side aperture, and
at least a second CCA (CCA2) comprising a second substrate having surface electrical conductors on at least one of a top side and bottom side located proximate to one of its edges (“connectable edge”);
wherein said connectable edge of said CCA2 penetrates into said board receiving side aperture of said CCA1 to provide a perpendicular attachment including a plurality of reinforced joints for communicating signals between said CCA1 and said CCA2,
wherein said plurality of reinforced joints provide at least partially filled volumes for at least one of above and below said CCA2 in fillable interface regions defined by a non-solder electrically conducting feature in said electrical conductor lined through-holes, and
wherein said reinforced joints comprise a low temperature flowable material that electrically connects respective ones of said surface conductors on at least one of said top side and said bottom sides of said CCA2 to respective ones of said plurality of electrical conductor lined through-holes on said CCA1.

2. The CCCA of claim 1, wherein said CCA2 has said surface electrical conductors on both said top side and said bottom side, and wherein said at least partially filled volumes are provided both above and below said CCA2 in said fillable interface regions.

3. The CCCA of claim 1, wherein said board receiving side aperture is slot-shaped and sized to receive said connectable edge of said CCA2.

4. The CCCA of claim 1, wherein said non-solder electrically conducting features comprise metal wires, and wherein said plurality of electrical conductor lined through-holes are large enough in size to fit said metal wires above and below said CCA1.

5. The CCCA of claim 4, wherein said CCA2 has said surface electrical conductors on both said top side and said bottom side and wherein said metal wires extend continuously across said connectable edge between said surface conductors on said top side and said bottom side of said CCA2.

6. The CCCA of claim 4, wherein said CCA2 has said surface electrical conductors on both said top side and said bottom side and wherein said metal wires do not extend continuously across said connectable edge, and wherein separate ones of said metal wires contact said surface conductors on said top side and said bottom side of said CCA2.

7. The CCCA claim 1, wherein said low temperature flowable material comprises solder, wherein said reinforced joints comprises reinforced solder joints, and wherein said metal wires comprise a metal or metal alloy that provides a melting point of at least 300° C.

8. The CCCA of claim 7, wherein said reinforced solder joints comprise gap-free reinforced solder joints, and wherein said reinforced solder joints tolerate at least 10,000 g's.

9. The CCCA of claim 1, wherein said non-solder electrically conducting feature comprises a press fittable metal or metal alloy that provides said low temperature flowable material.

10. The CCCA of claim 1, wherein said at least one board receiving side aperture comprises a plurality of board receiving side apertures, and wherein said least a CCA2 comprises a plurality of said CCA2's.

11. A method of assembling a coupled circuit card assemblies (CCCA), comprising:
inserting a second CCA (CCA2) comprising a second substrate having surface electrical conductors on at least one of its top side and bottom sides located proximate to one of its edges (“connectable edge”) including non-solder electrically conducting features bridging said surface electrical conductors on said top side and said bottom side into a first CCA (CCA1) comprising a first substrate having at least one board receiving side aperture in said first substrate having a plurality of electrical conductor lined through-holes located above and below said board receiving side aperture to provide a perpendicular insertion, and
electrically connecting said non-solder electrically conducting features to said electrical conductor lined through-holes to provide a plurality of at least partially filled reinforced joints for at least one of above and below said CCA2,
wherein said plurality of partially filled reinforced joints electrically connect respective ones of said surface conductors on at least one of said top side and said bottom side of said CCA2 to said plurality of electrical conductor lined through-holes on said CCA1.

12. The method of claim 11, wherein said CCA2 has said surface electrical conductors on both said top side and said bottom side, wherein said electrically connecting comprises soldering to provide at least partially filled volume reinforced solder joints both above and below said CCA2.

13. The method of claim 11, further comprising cutting said non-solder electrically conducting features to provide two separate electrically isolated conductors.

14. The method of claim 11, wherein said electrically connecting comprises soldering, and wherein said partially filled reinforced joints comprises reinforced solder joints, wherein said non-solder electrically conducting features comprise metal wires, and wherein a plurality of said metal wires are joined to one another with a dielectric material before said inserting, further comprising dissolving said dielectric material before said soldering.

15. The method of claim 11, wherein said non-solder electrically conducting features comprise metal wires, and wherein said plurality of electrical conductor lined through-holes are large enough in size to fit said metal wires above and below said CCA1.

16. The method of claim 11, wherein said low temperature flowable material comprises solder, wherein said reinforced joints comprises a reinforced solder joints, wherein said metal wires comprise a metal or metal alloy that provides a melting point of at least 300° C. and wherein said reinforced solder joints comprise gap-free reinforced solder joints, said gap-free reinforced solder joints tolerating at least 10,000 g's.

17. The method of claim 11, wherein said electrically connecting comprises press fitting.

18. A coupled circuit card assemblies (CCCA), comprising:
a first circuit card assembly (CCA1) comprising a first substrate having at least one board receiving side aperture in said first substrate having a plurality of electrical conductor lined through-holes located above and below said board receiving side aperture, and
at least a second CCA (CCA2) comprising a second substrate having surface electrical conductors on at least one of a top side and bottom side located proximate to one of its edges (“connectable edge”);
wherein said connectable edge of said CCA2 penetrates into said board receiving side aperture of said CCA1 to provide a perpendicular attachment including a plurality of reinforced solder joints for communicating signals between said CCA1 and said CCA2,
wherein said plurality of reinforced solder joints provide filled volumes for at least one of above and below said CCA2 in fillable interface regions defined by a non-solder electrically conducting feature in said electrical conductor lined through-holes, and
wherein said reinforced solder joints comprise solder and at least one of said non-solder electrically conducting features embedded in said solder that electrically connects respective ones of said surface conductors on at least one of said top side and said bottom side of said CCA2 to respective ones of said plurality of electrical conductor lined through-holes on said CCA1.

19. The CCCA of claim 18, wherein said metal wires comprise a metal or metal alloy that provides a melting point of at least 300° C., and wherein said reinforced solder joints comprise gap-free reinforced solder joints, said gap-free reinforced solder joints tolerating at least 10,000 g's.
